(19) United States
(12) Patent Application Publication
(10) Pub. No.: US 2008/0002370 A1
(43) Pub. Date: Jan. 3, 2008

(54) Scalable memory DIMM designs with vertical stackup connector

(76) Inventors: Wai Shin Lau, Penang (MY); Giap Yong Ooi, Penang (MY)

Correspondence Address: BLAKELY SOKOLOFF TAYLOR & ZAFMAN, 1279 OAKMEAD PARKWAY, SUNNYVALE, CA, 94085-4040, US

(21) Appl. No.: 11/480,145

(22) Filed: Jun. 30, 2006

(51) Int. Cl. H05K 7/00

(52) U.S. Cl. 361/735; 361/760

(57) ABSTRACT

A plurality of memory modules are vertically stacked on a printed circuit board (PCB). Each memory module includes a socket located on a longitudinal side to receive an overlying memory module in the stack. Each memory module also includes a connecter underneath the socket to be inserted into a socket of an underlying memory module or the PCB. The front side of each memory module in the stack is substantially parallel to the front side of the PCB.

### BACKGROUND

1. Field

Memory module layout on a printed circuit board (PCB).

2. Background

A current trend of the printed circuit board (PCB) design is to move toward a small board form factor to facilitate a compact system configuration. Typically, a significant area of the PCB is occupied by system memory modules. Thus, designing memory modules that can efficiently utilize the board space has become a challenging task.

The space reserved for memory modules on the PCB is often determined before the actual need of an end user is known. Typically, circuit designers reserve a fixed amount of space (e.g., four memory slots) on the PCB even though only one memory slot may be eventually used. It is generally difficult to standardize the amount of space reserved for the system memory as the amount of memory is often influenced by many unpredictable factors. For example, different end users may have different requirements on memory capacity. Floating market prices of memory modules may also influence the amount of memory installed on a computing device. It would be a waste of board space if a system is designed to accommodate several slots of memory modules but the end user only utilizes a small percentage of that capacity.

### BRIEF DESCRIPTION OF THE DRAWINGS

Embodiments are illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

FIG. 1 shows a block diagram of an embodiment of a computing system including a printed circuit board (PCB) having a single memory socket.

FIG. 2 shows an example of a plurality of memory modules vertically stacked on the PCB of FIG. 1.

FIG. 3 shows an embodiment of the memory module of FIG. 2.

FIG. 4 is a flow chart showing an example process of stacking the memory modules.

### DETAILED DESCRIPTION

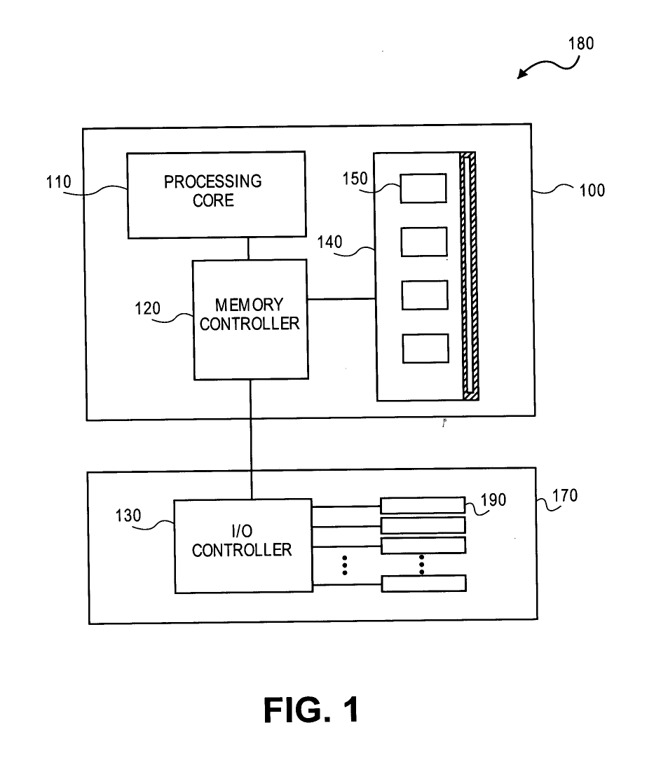

FIG. 1 shows an embodiment of a printed circuit board (PCB) 100 that forms a motherboard of a computing system 180. The computer system 100 includes at least one processing core 110, a memory controller 120, and a memory module 140 on the PCB board. In the embodiment as shown, processing core 110 and memory controller 120 are implemented by separate chips. It is understood that in alternative embodiments processing core 110 and memory controller 120 may be on the same chip.

PCB 100 may be installed in desktop/laptop computers, servers, cellular phones, personal digital assistants, local area network interfaces, network bridges or routers, or any other suitable wired or wireless systems.

Memory module 140 described herein refers to a memory board that includes a plurality of packaged memory chips 150. Each memory chip 150 may be a dynamic random access memory (DRAM), synchronous DRAM (SDRAM), static RAM (SRAM), extended data output (EDO) DRAM, or any other volatile or nonvolatile memory chips suitable for use as the system memory of computing system 180. In one embodiment, memory module 140 may be a dual in-line memory module (DIMM), a single in-line memory module (SIMM), or any other suitable memory module that contains a plurality of memory chips 150 described above. A DIMM typically has a 64-bit data path and includes two independent sets of electrical contacts on the front and back sides of the module. Thus, data transfer speed of a DIMM may be doubled compared to that of a SIMM.

In one embodiment, computing system 180 may also include an input/output (I/O) board 170 that includes an I/O controller 130 providing I/O slots 190 for connecting to a plurality of I/O devices. I/O controller 130 provides an interface for processing core 110 and other components of computing system 180 to access to I/O devices (not shown). The I/O devices may include Industry Standard Architecture (ISA) devices, Peripheral Component Interconnect (PCI) devices, PCI Express devices, Universal Serial Bus (USB) devices, Small Computer System Interface (SCSI) devices, or other standard or proprietary I/O devices suitable for personal or server applications.

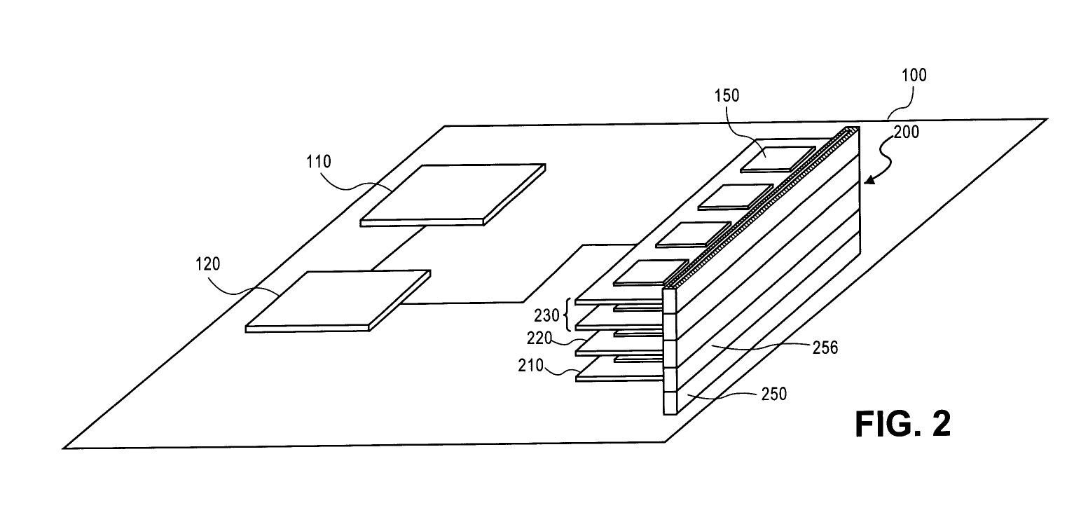

FIG. 2 shows an embodiment of a plurality of memory modules (e.g., memory module 140) forming a vertical stack 200 on a front side of PCB 100. Each memory module is mounted on PCB 100 such that the front/back side of the memory module is substantially parallel with respect to the front side of PCB 100. The front/back side of the memory module is also substantially parallel with respect to the front/back side of another memory module in stack 200. Memory modules in stack 200 may be identical memory modules, or may be memory modules that contain different types of chips but function together as system memory. In stack 200, a first memory module 210 may be directly plug-in to the memory socket that first mounted 250 on the PCB 100 and a second memory module 220 may be plug in to the second memory socket 260 and then mounted on top of first memory socket 210. Any number of additional memory modules 230 may be mounted on top of second memory module 220. Memory module mentioned above is non different from the commonly able to obtain from the market.

The vertical configuration allows a user to easily adjust the number of memory modules on PCB/computer system 100 according to his/her needs. A single memory socket on PCB 100 is sufficient to assemble multiple memory modules on board. Additional memory sockets on PCB 100 may be provided to allow multiple memory stacks on the PCB but is not generally required. Compared to a conventional design where four memory sockets are required to mount four memory modules, the configuration of stack 200 may save up to 75% memory socket space. Moreover, the stacked configuration has a lower profile compared to the conventional design that has the same number of memory modules. Thus, the stacked configuration may be implemented in a system that has height and space constraints.

Additionally, the stacked configuration allows board designers or end users to select memory modules based on the current memory price when the memory is installed into the system. For example, a system design may call for one gigabytes (G) of system memory. To achieve the required memory capacity, a designer may choose four 256-megabyte (M) memory modules, two 512M memory modules, or one 1G memory module. No matter which memory modules are eventually installed in the system, one memory socket on PCB 100 is sufficient to accommodate any combination of the memory modules. Thus, a memory design change will produce substantially zero impact on the PCB design.

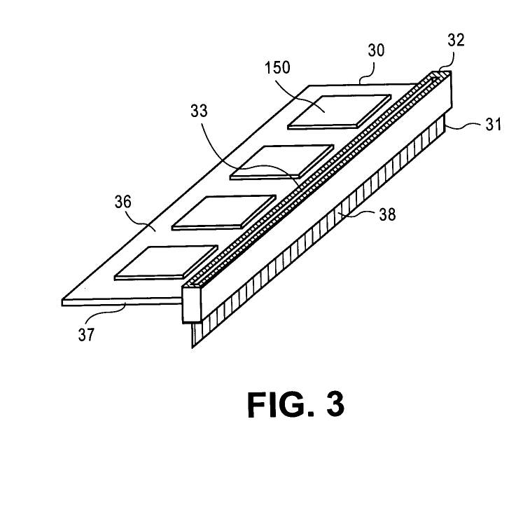

FIG. 3 is an embodiment of a memory module 30 that may be vertically stacked on a PCB. In one embodiment, memory module 30 may include a socket 32 on accessible from a front side 36 of the memory module, and a connector 31 accessible from a back side 37 of the memory module. Socket 32 may be located on a longitudinal side of memory module 30 and connector 31 may be located directly underneath socket 32. Connector 31 includes a plurality of electrical conducting lines 38 for routing signals in and out of memory module 30. In one embodiment, connector 31 extends from the longitudinal side of memory module 30 to form a substantially perpendicular (90°) angle with respect to back side 37 of the memory module. In alternative embodiments, the angle between connector 31 and back side 37 may be any suitable angle that allows the connector to be securely inserted into a socket. Connector 31 may be inserted into the socket of another memory module positioned below memory module 30 in the stack, such that after the insertion, front side 36/back side 37 of memory module 30 is substantially parallel to the front/back side of the underlying memory module. Connector 31 may also be inserted into the memory socket of the PCB, such that after the insertion, front side 36/back side 37 of memory module 30 is substantially parallel to the front side of the PCB. The memory should be free to be removed from the socket/connector when any replacement of memory is needed.

Socket 32 may include slot 33 to receive the connector of yet another memory module that overlies memory module 30. Inside slot 33, there may be a plurality of conductors (not shown) forming electrical contacts with the connector of the overlying memory module. The conductors of socket 32 are electrically connected to conducting lines 38 of connector 31 of the same memory module 30. Thus, memory module 30 may forward electrical signals between any memory module in the stack and the components on the PCB. The electrical signals may include address, data, control, clock, and any other suitable signals. The memory is not permanently mounted on the socket and able to be removed from the socket.

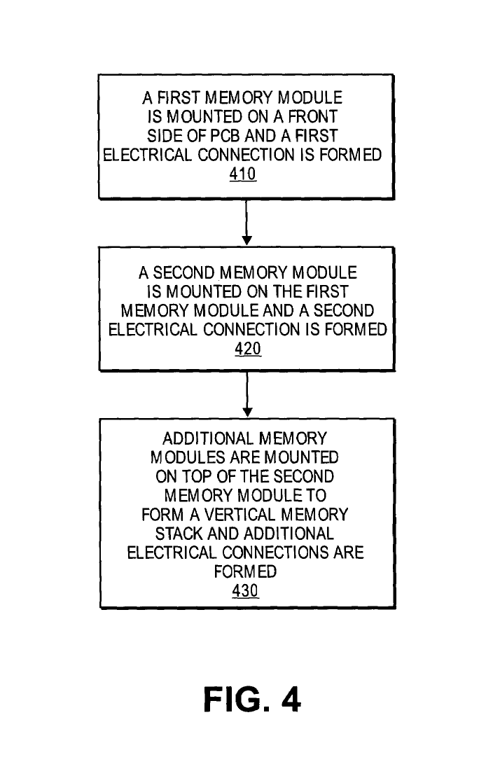

FIG. 4 is a flow chart showing an example of a process for stacking the memory modules (e.g., memory module 30 of FIG. 3). At block 410, a first memory module is mounted on a front side of PCB by inserting its connector into a memory socket of the PCB. After mounting on the PCB, a first electrical connection is formed between the first memory module and the PCB. At block 420, a second memory module is mounted on the first memory module by inserting its connector into the socket of the first memory module. After mounting on the first memory module, a second electrical connection is formed between the second memory module and the first memory module and the PCB. At block 430, additional memory modules may be mounted on top of the second memory module to form a vertical memory stack. After mounting on the second memory module, additional electrical connections are formed between the additional memory modules and the first memory module, second memory module, and the PCB. It is understood that the memory modules may be mounted in an order different from the above description. For example, the memory modules may be vertically stacked before mounting the entire stack on the PCB.

In the foregoing specification, specific embodiments have been described. It will, however, be evident that various modifications and changes can be made thereto without departing from the broader spirit and scope of the appended claims. The specification and drawings are, accordingly, to be regarded in an illustrative rather than a restrictive sense.

What is claimed is:

1. A method comprising:
stacking a plurality of memory modules in a vertical stack on a front side of a printed circuit board (PCB); and
electrically connecting the memory modules to the PCB.

2. The method of claim 1 wherein stacking the plurality of memory modules comprises:
installing the plurality of memory modules on the PCB such that a front side of each of the memory modules is substantially parallel to the front side of the PCB.

3. The method of claim 1 wherein stacking the plurality of memory modules further comprises:
providing a socket on each of the memory modules to receive another memory module.

4. The method of claim 1 wherein stacking the plurality of memory modules further comprises:
providing a connector on each of the memory modules to be inserted into a socket of another memory module.

5. The method of claim 1 wherein stacking the plurality of memory modules further comprises:
providing a socket on a longitudinal side of each of the memory modules;
providing a connector underneath of the socket; and
forming electrical contacts between the socket and the connector.

6. The method of claim 1 wherein electrically connecting the memory modules to the PCB comprises:
providing a connector on each of the memory modules to be inserted into a socket of the PCB.

7. An apparatus comprising:
a printed circuit board (PCB); and
at least one memory module mounted on the PCB, wherein the memory module includes:
a connector; and
a socket to receive another memory module.

8. The apparatus of claim 7 wherein the PCB comprises:
a plurality of memory modules mounted on the PCB in a vertical stack.

9. The apparatus of claim 7 wherein the PCB further comprises:
a memory socket to receive the memory module such that a front side of the memory module is substantially parallel to a front side of the PCB.

10. The apparatus of claim 7 wherein the socket of the memory module is located on a longitudinal side of the memory module.

11. The apparatus of claim 7 wherein the connector of the memory module is underneath the socket and the connector is substantially perpendicular with respect to a back side of the memory module.

12. The apparatus of claim 7 wherein the memory module further comprises:
a dual in-line memory module (DIMM).

13. The apparatus of claim 7 wherein the memory module further comprises:
a plurality of memory chips mounted on the memory module.

14. A system comprising:
a printed circuit board (PCB); and
at least one dual in-line (DIMM) memory module mounted on the PCB, wherein the memory module includes:
a connector; and
a socket to receive another memory module.

15. The system of claim 14 wherein the PCB comprises:
a plurality of memory modules mounted on the PCB in a vertical stack.

16. The system of claim 15 wherein the PCB further comprises:
a memory socket to receive the vertical stack such that a front side of each memory module in the vertical stack is substantially parallel to a front side of the PCB.

17. The system of claim 15 wherein the PCB further comprises:
a memory socket to receive the memory module such that a front side of the memory module is substantially parallel to a front side of the PCB.

18. The system of claim 14 wherein the socket of the memory module is located on a longitudinal side of the memory module.

19. The system of claim 14 wherein the connector of the memory module is underneath the socket and the connector is substantially perpendicular with respect to a back side of the memory module.

20. The system of claim 14 wherein the memory module further comprises:
a plurality of synchronous dynamic random access memory (SDRAM) devices.
